(19) United States
(12) Patent Application Publication
(10) Pub. No.: US 2025/0251425 A1
(43) Pub. Date: Aug. 7, 2025

(54) CURRENT DETECTION DEVICE

(71) Applicant: HONDA MOTOR CO., LTD., Tokyo (JP)

(72) Inventors: Kosuke KAJITA, Tokyo (JP); Shotaro KARASUYAMA, Tokyo (JP); Jiro FUKUI, Tokyo (JP)

(21) Appl. No.: 19/045,573

(22) Filed: Feb. 5, 2025

(30) Foreign Application Priority Data
Feb. 7, 2024 (JP) 2024-017475

(51) Int. Cl. G01R 15/14; G01R 19/00

(52) U.S. Cl. CPC G01R 15/14; G01R 19/0092

(57) ABSTRACT

A current detection device includes two magnetism detection elements Sα, Sβ that are provided in the vicinities of current lines 6u, 6v, and 6w, and a current correction calculation unit 22 that outputs, as α-phase and β-phase current values (Iα, Iβ), the output values (Vα, Vβ) of the respective magnetism detection elements Sα and Sβ with α-phase and β-phase gains (Gα, Gβ) multiplied thereby. The relative positions of the two magnetism detection elements Sα and Sβ and the orientations of the detection axes thereof with respect to the three phase current lines 6u, 6v, and 6w are set such that an α-phase layout conditional expression and a β-phase layout conditional expression, which are defined using a factor X other than “−½,” are satisfied. The values of the α-phase and β-phase gains (Gα, Gβ) are set such that the amplitudes of the α-phase and β-phase current values (Iα, Iβ) are equal.

This application is based on and claims the benefit of priority from Japanese Patent Application No. 2024-017475, filed on 7 Feb. 2024, the content of which is incorporated herein by reference.

### BACKGROUND OF THE INVENTION

### Field of the Invention

The present invention relates to a current detection device. More particularly, the present invention relates to a current detection device that detects the current of each phase of a three-phase motor on the basis of two magnetism detection elements.

### Related Art

In recent years, efforts toward the realization of a low-carbon society or a decarbonized society have been activated, and research and development pertaining to electric vehicles have been carried out in order to reduce CO₂ emissions of vehicles and improve the energy efficiency thereof.

What is called vector control is widely employed as a method for controlling a three-phase AC motor equipped in, for example, an electric vehicle or a household electrical appliance (e.g., air conditioner, washing machine). In the vector control, a motor control device generates a command signal for an inverter on the basis of feedback control of a d-axis current and a q-axis current that are defined on d-q coordinates, which constitute a rotary, orthogonal coordinate system specific to a motor.
Patent Document 1: PCT International Publication No. WO2013/058282
Patent Document 2: Chinese Patent Application No. 202211040361. X

### SUMMARY OF THE INVENTION

The motor control device performs current feedback control on d-q coordinates as described above, and thus needs to convert the U-phase current, V-phase current, and W-phase current of the motor detected using a current detection device such as that disclosed in, for example, PCT International Publication No. WO2013/058282 into a d-axis current and a q-axis current. More specifically, the motor control device first converts, through Clarke transform, a three-phase current (Iu, Iv, Iw) detected by the current detection device into a two-phase current (Iα, Iβ) defined on a fixed-coordinate system, and then converts the two-phase current (Iα, Iβ) into a two-phase current (Id, Iq) defined on the d-q coordinate system through Park transform using the rotation angle θ of the motor. In the vector control using the output of the conventional current detection device, as noted above, the motor control device needs to perform calculation for converting a three-phase current (Iu, Iv, Iw) into a two-phase current (Id, Iq).

Meanwhile, Chinese Patent Application No. 202211040361. X, which is an application by the applicant of the present application, describes the technique of providing two magnetism detection elements at positions geometrically set in the vicinity of three phase current lines so as to directly obtain a two-phase current (Iα, Iβ) without performing the Clarke transform based on calculation performed by a computer (such a technique may hereinafter be referred to as the “space Clarke transform”). In comparison with the prior art, the space Clarke transform allows for decreasing the number of magnetism detection elements and reducing the computational load on the computer.

According to the space Clarke transform disclosed in Chinese Patent Application No. 202211040361. X, however, the disposition layout of the three phase current lines and the two magnetism detection elements is limited to only several patterns. Since various components need to be disposed in an electric vehicle efficiently, the degree of freedom in the disposition layout of phase current lines and magnetism detection elements is preferably as high as possible.

An object of the present invention is to provide a current detection device for a three-phase motor, the current detection device being capable of reducing the computational load on a motor control device on a subsequent stage that performs vector control, and ultimately to contribute to the improvement of energy efficiency.
(1) A current detection device (e.g., current detection device 3 described hereinafter) according to the present invention detects currents flowing through a first current line (e.g., U-phase current line 6u described hereinafter), a second-phase current line (e.g., V-phase current line 6v described hereinafter), and a third-phase current line (e.g., W-phase current line 6w described hereinafter) of a three-phase motor (e.g., motor M described hereinafter), the current detection device including an α-phase magnetism detection element (e.g., α-phase magnetism detection element Sa described hereinafter) and a β-phase magnetism detection element (e.g., β-phase magnetism detection element SB described hereinafter) that are provided in the vicinities of the first-phase, second-phase, and third-phase current lines, and a calculator (e.g., current correction calculation unit 22 described hereinafter) that outputs, as an α-phase current value (e.g., α-phase current value Iα described hereinafter) and a β-phase current value (e.g., β-phase current value Iβ described hereinafter), the output values of the α-phase and β-phase magnetism detection elements with an α-phase gain (e.g., α-phase gain Gα described hereinafter) and a β-phase gain (e.g., β-phase gain Gβ described hereinafter) respectively multiplied thereby, wherein assuming that I1 is the current value of the current flowing through the first-phase current line, I2 is the current value of the current flowing through the second-phase current line, I3 is the current value of the current flowing through the third-phase current line, Vα is the output value of the α-phase magnetism detection element, and VB is the output value of the β-phase magnetism detection element, the relative positions of the α-phase and β-phase magnetism detection elements and the orientations of the detection axes thereof with respect to the first-phase, second-phase, and third-phase current lines are set such that the expressions (1-1) and (1-2) below, which are defined using a factor X other than “−½,” are satisfied, and the values of the α-phase and β-phase gains are set such that the amplitudes of the α-phase and β-phase current values are equal.

$$V α ∝ ( \begin{matrix}X & - 1 / 2 & - 1 / 2\end{matrix} ) ( \begin{matrix}I 1 \\ I 2 \\ I 3\end{matrix} ) \qquad ( 1 - 1 )$$

$$V β ∝ ( \begin{matrix}0 & \sqrt{3} / 2 & - \sqrt{3} / 2\end{matrix} ) ( \begin{matrix}I 1 \\ I 2 \\ I 3\end{matrix} ) \qquad ( 1 - 2 )$$

(2) In this case, it is preferable that the α-phase and β-phase magnetism detection elements are provided within the same disposition plane (e.g., disposition plane P described hereinafter) orthogonal to the first-phase, second-phase, and third-phase current lines.
(3) In this case, it is preferable that the α-phase magnetism detection element is disposed on an imaginary disposition line (e.g., α-phase disposition line La described hereinafter) that is orthogonal to a line segment (e.g., line segment Li described hereinafter) connecting the second-phase current line and the third-phase current line within the disposition plane and that bisects the line segment.
(4) In this case, it is preferable that: the first-phase current line is orthogonal to the disposition plane at the point of intersection of the line segment and the disposition line; and the orientations of direct currents flowing from a power supply through the first-phase, second-phase, and third-phase current lines toward the three-phase motor are the same within the disposition plane.
(5) In this case, it is preferable that the β-phase magnetism detection element is disposed on the disposition line within the disposition plane.
(6) In this case, it is preferable that the β-phase magnetism detection element is disposed on the disposition line such that the detection axis (e.g., detection axis OB described hereinafter) thereof is parallel to the disposition line.
(1) The current detection device according to the present invention detects currents flowing through three current lines on the basis of two magnetism detection elements provided in the vicinities of the current lines. Thus, the present invention allows for decreasing the number of magnetism detection elements in comparison with the conventional current detection device provided with one magnetism detection element for each single current line, so that the cost can be reduced accordingly. In the current detection device according to the present invention, the relative positions of the α-phase and β-phase magnetism detection elements and the orientations of the detection axes thereof with respect to the first-phase to third-phase current lines are set such that expressions (1-1) and (1-2), which are defined using a factor X other than “−½,” are satisfied. Meanwhile, in the space Clarke transform described in Chinese Patent Application No. 202211040361. X (which may be simply referred to as the “earlier application” hereinafter), which is an application by the applicant of the present application, the relative positions of the α-phase and β-phase magnetism detection elements and the orientations of the detection axes thereof with respect to the first-phase to third-phase current lines are set such that a matrix operation expression equivalent to the Clarke transform (corresponding to expressions (1-1) and (1-2) with X=1) is satisfied. Thus, in the present invention, expressions (1-1) and (1-2) include an arbitrary factor X, so the degree of freedom in the disposition layout of the three phase current lines and the two magnetism detection elements can be made higher than in the conventional space Clarke transform.

As described hereinafter in detail, a current that is obtained by multiplying a three-phase current (I1, I2, I3) having phases differing from each other by 2π/3 by the conversion matrix (X, −½, −½) indicated in expression (1-1) is different only in amplitude from, but has the same phase as, a current that is obtained by multiplying the three-phase current (I1, I2, I3) by the first-row elements (1, −½, −½) of the conversion matrix of the Clarke transform. This fact means that the output value Vα of the α-phase magnetism detection element provided in such a manner as to satisfy expression (1-1) can be made equal to the output value of the magnetism detection element described in the earlier application by being multiplied by a prescribed gain. Thus, in the present invention, the calculator outputs, as α-phase and β-phase current values, the output values of the α-phase and β-phase magnetism detection elements with the α-phase and β-phase gains respectively multiplied thereby. The values of the α-phase and β-phase gains are set such that the amplitudes of the α-phase and β-phase current values are equal. Thus, in the current detection device according to the present invention, the calculation performed by the calculator allows for the cancellation of the difference in amplitude between the output values of the two magnetism detection elements that is caused by the factor X included in expression (1-1). In the present invention, accordingly, since the α-phase and β-phase current values output from the calculator are used, the motor control device provided on a subsequent stage does not need to perform the Clarke transform through calculation. Hence, the computational load on the motor control device can be reduced accordingly, and the present invention can ultimately contribute to the improvement of energy efficiency.
(2) In the present invention, the α-phase and β-phase magnetism detection elements can be provided within a disposition plane orthogonal to the three phase current lines, thereby allowing the two magnetism detection elements to be gathered compactly and disposed in the vicinities of the three phase current lines, while satisfying expressions (1-1) and (1-2).
(3) In the present invention, the α-phase magnetism detection element can be disposed on an imaginary disposition line that is orthogonal to the line segment connecting the second-phase and third-phase current lines within the disposition plane and that bisects the line segment, thereby allowing the α-phase magnetism detection element to be disposed at an arbitrary position meeting needs, while satisfying expressions (1-1) and (1-2).
(4) In the present invention, the first-phase, second-phase, and third-phase current lines can be disposed next to each other, thereby allowing the three phase current lines to be gathered compactly, while satisfying expressions (1-1) and (1-2). Although the space Clarke transform described in the earlier application also allows three phase current lines to be disposed next to each other, the phase current lines need to be twisted because the orientation of the phase current line disposed in the middle needs to be opposite to the orientation of the other two (see FIGS. 4 and 5 of the earlier application). In the present invention, by contrast, the three phase current lines can be disposed next to each other without twisting the phase current lines.
(5) In the present invention, the three phase current lines can be disposed next to each other, and the α-phase and β-phase magnetism detection elements can be provided on a disposition line passing the first-phase current line, which is positioned in the middle, thereby allowing the three phase current lines and the two magnetism detection elements to be gathered compactly, while satisfying expressions (1-1) and (1-2).
(6) In the present invention, the β-phase magnetism detection element can be disposed on a disposition line such that the detection axis thereof is parallel to the disposition line, thereby allowing the β-phase magnetism detection element to be disposed near the first-phase current line, while preventing the influence of a current flowing through the first-phase current line from being exerted on the β-phase magnetism detection element.

### BRIEF DESCRIPTION OF THE DRAWINGS

FIG. 1 illustrates the configurations of a current detection device according to one embodiment of the present invention and an electric vehicle provided with the current detection device;

FIG. 2 illustrates a disposition range of an α-phase magnetism detection element, the disposition range being for satisfying an α-phase layout conditional expression;

FIG. 3 illustrates a disposition range of a β-phase magnetism detection element, the disposition range being for satisfying a β-phase layout conditional expression;

FIG. 4 illustrates a first example of the disposition layout of three phase current lines and two magnetism detection elements, the first example being for satisfying both the α-phase and β-phase layout conditional expressions within a disposition plane; and

FIG. 5 illustrates a second example of the disposition layout of three phase current lines and two magnetism detection elements, the second example being for satisfying both the α-phase and β-phase layout conditional expressions within a disposition plane.

### DETAILED DESCRIPTION OF THE INVENTION

The following describes a current detection device according to one embodiment of the present invention and an electric vehicle equipped with the current detection device by referring to the drawings.

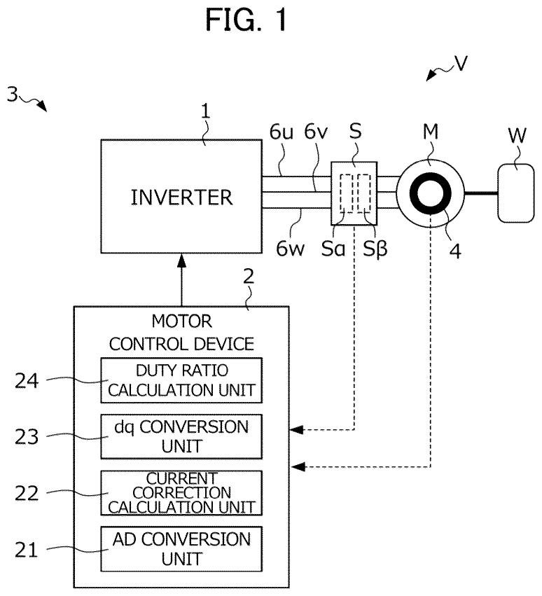

FIG. 1 illustrates the configurations of a current detection device 3 according to the present embodiment and an electric vehicle V provided with the current detection device. Although the following describes a situation in which the current detection device 3 is equipped in the electric vehicle V, the present invention is not limited to this. Besides the electric vehicle V, the current detection device 3 can be equipped in any configuration that controls a three-phase motor on the basis of vector control, such as an air conditioner or a washing machine.

The electric vehicle V is provided with a three-phase AC motor M (hereinafter simply referred to as the “motor M”), a drive wheel W that is coupled to the output shaft of the motor M via a power transmission mechanism (not illustrated), an inverter 1 that connects a battery (not illustrated) and the motor M, a sensor unit S that generates a signal corresponding to a current flowing through the motor M, a resolver 4 that detects the rotational position of the motor M, and a motor control device 2 that controls the inverter 1 on the basis of detection signals of the sensor unit S and the resolver 4.

For example, the inverter 1 is a PWM inverter based on pulse-width modulation that is provided with a bridge circuit formed by bridge-connecting a plurality of switching elements (e.g., IGBTs), and has a function for conversion between DC power and AC power. The inverter 1 has a DC input/output side connected to the battery and an AC input/output side connected to the U-phase, V-phase, and W-phase coils of the motor M, and converts power between the battery and the motor M. The inverter 1 performs the on/off driving of the switching elements for the respective phases in accordance with gate drive signals generated at prescribed timings from a gate drive circuit (not illustrated), thereby converting DC power supplied from the battery into AC power and then supplying the same to the motor M, or converting AC power supplied from the motor M into DC power and then supplying the same to the battery.

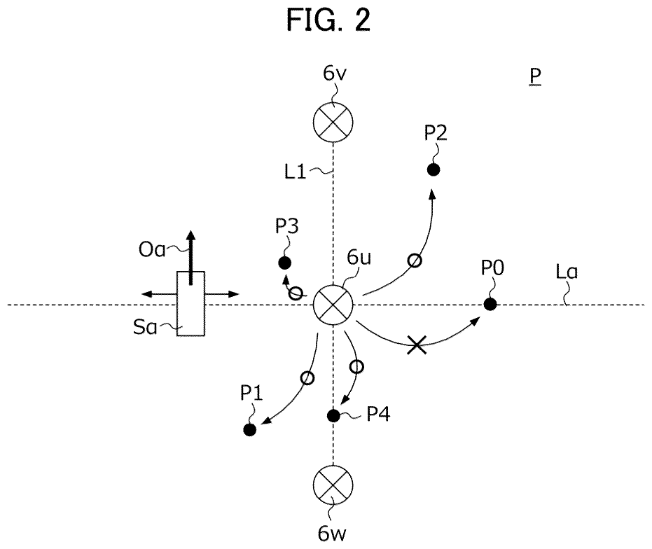

The sensor unit S is provided with an α-phase magnetism detection element Sa and a R-phase magnetism detection element Sβ provided in the vicinities of three phase current lines (U-phase current line 6u, V-phase current line 6v, and W-phase current line 6w) connecting the motor M and the inverter 1. The magnetism detection elements Sα and Sβ generate detection signals corresponding to components, along the detection axes thereof, of the magnetic flux densities of magnetic fields generated by currents flowing through the phase current lines 6u, 6v, and 6w. Note that specific examples of the disposition layout of the α-phase and β-phase magnetism detection elements Sα and Sβ and the three phase current lines 6u, 6v, and 6w are described hereinafter by referring to FIGS. 2 to 5.

The motor control device 2 is a computer that generates a drive signal for the gate drive circuit of the inverter 1 by performing vector control based on detection signals from the two magnetism detection elements Sα and Sβ and the resolver 4 and inputs the drive signal to the gate drive circuit.

An AD conversion unit 21, a current correction calculation unit 22, a dq conversion unit 23, and a duty ratio calculation unit 24 are formed for the motor control device 2 as modules pertaining to the execution of the above-noted vector control.

The AD conversion unit 21 applies AD conversion to detection signals of the α-phase and β-phase magnetism detection elements Sα and Sβ so as to obtain the output values (Vα, Vβ) of the α-phase and β-phase magnetism detection elements Sα and Sβ.

As indicated by equation (2) below, the current correction calculation unit 22 outputs, as an α-phase current value Iα and a β-phase current value Iβ, the output values (Vα, Vβ) of the respective α-phase and β-phase magnetism detection elements Sα and Sβ obtained by the AD conversion unit 21 with an α-phase gain Gα and a β-phase gain Gβ multiplied thereby. Note that the values of the α-phase and β-phase gains (Gα, Gβ) are set such that the amplitudes of the α-phase and β-phase current values (Iα, Iβ) are equal.

$$( \begin{matrix}I α \\ I β\end{matrix} ) = ( \begin{matrix}G α & G β\end{matrix} ) ( \begin{matrix}V α \\ V β\end{matrix} ) \qquad ( 2 )$$

As described hereinafter, the α-phase and β-phase current values (Iα, Iβ) calculated by the current correction calculation unit 22 are proportional to a two-phase current (Iα_ideal, Iβ_ideal) obtained by multiplying the three-phase current (Iu, Iv, Iw) of the motor M by a Clarke transform matrix with two rows and three columns such as that indicated by equation (3) below. In the following description, Iu is the current value of a current flowing through the U-phase current line 6u, Iv is the current value of a current flowing through the V-phase current line 6v, and Iw is the current value of a current flowing through the W-phase current line 6w. Thus, the motor control device 2 does not need to perform calculation using the Clarke transform matrix indicated by equation (3) when the dq conversion unit 23 (described hereinafter) calculates the two-phase current (Id, Iq) on the d-q coordinate system, so that the computational load on the motor control device 2 can be reduced accordingly in comparison with the prior art. In the present embodiment, accordingly, the current detection device 3, which detects currents flowing through the three-phase current lines 6u, 6v, and 6w of the motor M, is formed from the two magnetism detection elements Sα and Sβ, the AD conversion unit 21, and the current correction calculation unit 22.

$$( \begin{matrix}I α \\ I β\end{matrix} ) ∝ ( \begin{matrix}I α\_ideal \\ I β\_ideal\end{matrix} ) = ( \begin{matrix}1 & - 1 / 2 & - 1 / 2 \\ 0 & \sqrt{3} / 2 & - \sqrt{3} / 2\end{matrix} ) ( \begin{matrix}Iu \\ Iv \\ Iw\end{matrix} ) \qquad ( 3 )$$

The dq conversion unit 23 calculates a d-axis current Id and a q-axis current Iq by performing known calculation using the output values (Iα, Iβ) of the current correction calculation unit 22 and a detection signal of the resolver 4.

The duty ratio calculation unit 24 acquires a d-axis current command Idc and a q-axis current command Iqc corresponding to a driving force demanded by the driver, performs feedback control based on the deviations (Idc-Id, Iqc-Iq) of these current values, thereby generating a drive signal for the gate drive circuit of the inverter 1 so as to achieve the driving force demanded by the driver, and inputs the drive signal to the gate drive circuit.

Next, descriptions are given of conditions imposed on the disposition layout of the three phase current lines 6u, 6v, and 6w and the two magnetism detection elements Sα and Sβ in order to satisfy equation (3).

First, as described above, the current correction calculation unit 22 calculates α-phase and β-phase current values (Iα, Iβ) such that the amplitudes are equal, respectively by multiplying the output values (Vα, Vβ) of the α-phase and β-phase magnetism detection elements Sα and Sβ by α-phase and β-phase gains (Gα, Gβ). Accordingly, although the phase difference between the output values (Vα, Vβ) of the α-phase and β-phase magnetism detection elements Sα and Sβ needs to be equal to the phase difference in the two-phase current (Iα_ideal, Iβ_ideal) obtained from equation (3), the amplitudes of these output values (Vα, Vβ) may be different. In particular, the difference in amplitude between the output values (Vα, Vβ) may be canceled out by the current correction calculation unit 22 adjusting the values of the α-phase and β-phase gains (Gα, Gβ). Hence, equation (3) can be satisfied by disposing the three phase current lines 6u, 6v, and 6w and the two magnetism detection elements Sα and Sβ such that the following equations (4-1) and (4-2), which are respectively imposed on the two output values (Vα, Vβ), are satisfied.

$$V α ∝ T α\_ideal = ( \begin{matrix}1 & - 1 / 2 & - 1 / 2\end{matrix} ) ( \begin{matrix}Iu \\ Iv \\ Iw\end{matrix} ) \qquad ( 4 - 1 )$$

$$V β ∝ T β\_ideal = ( \begin{matrix}0 & \sqrt{3} / 2 & - \sqrt{3} / 2\end{matrix} ) ( \begin{matrix}Iu \\ Iv \\ Iw\end{matrix} ) \qquad ( 4 - 2 )$$

As described hereinafter, assuming that the current values (Iu, Iv, Iw) of currents flowing through the phase current lines 6u, 6v, and 6w each have a phase difference of 2π/3 from the others, equations (4-1) and (4-2) can be generalized into the expressions (5-1) and (5-2) below by using an arbitrary factor X. In the present embodiment, accordingly, the disposition layout of the three phase current lines 6u, 6v, and 6w and the two magnetism detection elements Sα and Sβ (i.e., the disposition layout of the three phase current lines 6u, 6v, and 6w and the relative positions of the two magnetism detection elements Sα and Sp and the orientations of the detection axes thereof with respect to the phase current lines 6u, 6v, and 6w) is set such that expressions (5-1) and (5-2), which are defined using a factor X other than “−1,” are satisfied. In the case of such a disposition layout as to be accompanied by “−½” as the value of the factor X in expression (5-1), the output value of the magnetism detection element Sa would be stationarily “0” in theory. Hence, for expression (5-1), disposition layouts accompanied by “−½” as the value of the factor X are excluded.

$$V α ∝ ( \begin{matrix}X & - 1 / 2 & - 1 / 2\end{matrix} ) ( \begin{matrix}Iu \\ Iv \\ Iw\end{matrix} ) \qquad ( 5 - 1 )$$

$$V β ∝ ( \begin{matrix}0 & \sqrt{3} / 2 & - \sqrt{3} / 2\end{matrix} ) ( \begin{matrix}Iu \\ Iv \\ Iw\end{matrix} ) \qquad ( 5 - 2 )$$

The following describes the reason for the capability to generalize equation (4-1) into expression (5-1). When the α-phase magnetism detection element Sa and the three phase current lines 6u, 6v, and 6w have been each disposed at an arbitrarily position, an output value Vα′ of the α-phase magnetism detection element Sa is represented by equation (6) below using arbitrary factors (X, A, B). The values of the factors (X, A, B) vary according to the relative position of the α-phase magnetism detection element Sa and the orientation of the detection axis thereof with respect to the three phase current lines 6u, 6v, and 6w. More specifically, the value of the factor X is determined according to the relative position of the α-phase magnetism detection element Sa and the orientation of the detection axis thereof with respect to the U-phase current line 6u, the value of the factor A is determined according to the relative position of the α-phase magnetism detection element Sa and the orientation of the detection axis thereof with respect to the V-phase current line 6v, and the value of the factor B is determined according to the relative position of the α-phase magnetism detection element Sa and the orientation of the detection axis thereof with respect to the W-phase current line 6w.

$$V {α}^{′} = X \cdot Iu + A \cdot Iv + B \cdot Iw \qquad ( 6 )$$

Assuming that the current values (Iu, Iv, Iw) of currents flowing through the phase current lines 6u, 6v, and 6w each have a phase difference of 2π/3 from the others with reference to the U-phase, equation (7) below is derived from equation (6) according to an addition theorem. In equation (7), Iu=sin θ, Iv=sin (θ-2π/3), and Iw=sin (θ+2π/3).

$$V {α}^{′} = \frac{1}{2} \cdot ( 2 X - A - B ) \cdot sin θ + \frac{\sqrt{3}}{2} \cdot ( A - B ) \cdot cos θ \qquad ( 7 )$$

Assuming that, as in equation (4-1), A=B is satisfied in equation (7), equation (8) below is derived. The assumption of A=B being satisfied corresponds to the disposing of the phase current lines 6v and 6w and the α-phase magnetism detection element Sa at such positions that: the distance between the V-phase current line 6v and the α-phase magnetism detection element Sa is equal to the distance between the W-phase current line 6w and the α-phase magnetism detection element Sa; and an angle that is formed by a line segment connecting the V-phase current line 6v and the α-phase magnetism detection element Sα with the detection axis of the α-phase magnetism detection element Sα is equal to an angle that is formed by a line segment connecting the W-phase current line 6w and the α-phase magnetism detection element Sα with the detection axis of the α-phase magnetism detection element Sα.

$$V {α}^{′} = ( X - A ) \cdot sin θ \qquad ( 8 )$$

Assuming that A=B is satisfied, as indicated by equation (8), the term of cos θ is deleted from equation (7), and the output value Vα′ of the α-phase magnetism detection element Sα is proportional to sin θ alone. This fact means that, within the range in which A=B is satisfied, the phase of the output value Vα′ does not change, regardless of how the relative position of the α-phase magnetism detection element Sα and the orientation of the detection axis thereof with respect to the U-phase current line 6u is changed (i.e., regardless of how the value of X changes). In other words, the fact means that, within the range in which A=B is satisfied, only the amplitude of the output value Vα′ changes, regardless of how the relative position of the α-phase magnetism detection element Sα and the orientation of the detection axis thereof with respect to the U-phase current line 6u is changed (i.e., regardless of how the value of X changes). As indicated by equation (8), the output value Vα′ is stationarily “0” when the α-phase magnetism detection element Sα is disposed at such a position that the values of all the factors are equal (i.e., such a position that X=A=B is satisfied). For such a reason, equation (4-1) can be generalized as indicated by expression (5-1) by using an arbitrary factor X excluding “−½.”

Next, descriptions are given of the disposition layout of the three phase current lines 6u, 6v, and 6w and the two magnetism detection elements Sα and Sβ for satisfying expressions (5-1) and (5-2). In the following descriptions, expression (5-1), which is imposed on the output value Vα of the α-phase magnetism detection element Sα, is referred to as the α-phase layout conditional expression, and expression (5-2), which is imposed on the output value VB of the β-phase magnetism detection element SB, is referred to as the β-phase layout conditional expression. Meanwhile, although the following describes a situation in which the two magnetism detection elements Sα and Sβ are disposed within the same disposition plane orthogonal to the three phase current lines 6u, 6v, and 6w, the present invention is not limited to this. The two magnetism detection elements Sα and Sβ may be provided within different disposition planes.

FIG. 2 schematically illustrates a disposition plane P for two magnetism detection elements Sα and Sβ, which is orthogonal to three phase current lines 6u, 6v, and 6w. More specifically, FIG. 2 illustrates a disposition range of the α-phase magnetism detection element Sα within the disposition plane P, the disposition range being for satisfying α-phase layout conditional expression (5-1). Although FIG. 2 depicts a situation in which the three phase current lines 6u, 6v, and 6w are disposed within the disposition plane P next to each other at equal intervals such that the V-phase current line 6v, the U-phase current line 6u, and the W-phase current line 6w are arranged in this order, the present invention is not limited to this. Furthermore, although FIG. 2 depicts a situation in which, within the disposition plane P, direct currents flow in the same orientation from the inverter 1, which is a power supply, through the phase current lines 6u, 6v, and 6w toward the motor M, the present invention is not limited to this. In order to facilitate understanding, the β-phase magnetism detection element SB is not depicted in FIG. 2.

First, in order to satisfy α-phase layout conditional expression (5-1), the α-phase magnetism detection element Sα needs to be disposed on an imaginary α-phase disposition line Lα that is orthogonal to an imaginary line segment Li connecting the V-phase current line 6v and the W-phase current line 6w within the disposition plane P and that bisects the line segment Li. That is, the α-phase magnetism detection element Sα needs to be disposed at a position where the distances thereof to the V-phase current line 6v and the W-phase current line 6w within the disposition plane P are equal (i.e., needs to be disposed on the α-phase disposition line La).

Meanwhile, in order to satisfy α-phase layout conditional expression (5-1), the detection axis Oα of the α-phase magnetism detection element Sα needs to be orthogonal to the α-phase disposition line La within the disposition plane P, as exemplified in FIG. 2. In this case, however, the detection axis Oα and a magnetic flux formed by the phase current lines 6v and 6w will be orthogonal to each other if the α-phase magnetism detection element Sα is disposed at the point of intersection of the line segment Li and the α-phase disposition line La. Thus, the α-phase magnetism detection element Sα needs to be disposed on the α-phase disposition line Lα at a position other than the point of intersection with the line segment Li.

As noted above, α-phase layout conditional expression (5-1) includes an arbitrary factor X. Hence, the U-phase current line 6u may be provided at any position within the disposition plane P, excluding a dead point P0 at which the value of the factor X is “−½.”

In particular, without being limited to the midpoint of the line segment Li depicted in FIG. 2, α-phase layout conditional expression (5-1) is also satisfied when the U-phase current line 6u is disposed within the disposition plane P at a position such as that indicated by, for example, a point P1, P2, P3, or P4. In this regard, the dead point P0 is a disposition position for the U-phase current line 6u at which the output value Vα of the α-phase magnetism detection element Sα is stationarily “0,” as described above. When the α-phase magnetism detection element Sα and the v-phase and w-phase current lines 6v and 6w are provided at positions such as those indicated in FIG. 2, the dead point P0 emerges on the α-phase disposition line Lα, as depicted in FIG. 2.

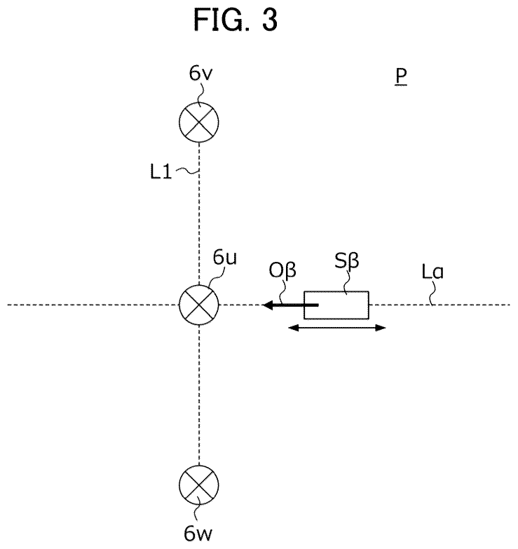

FIG. 3 schematically illustrates a disposition plane P for two magnetism detection elements Sα and Sβ, which is orthogonal to three phase current lines 6u, 6v, and 6w. More specifically, FIG. 3 illustrates a disposition range of a β-phase magnetism detection element SB within the disposition plane P, the disposition range being for satisfying β-phase layout conditional expression (5-2). In order to facilitate understanding, the α-phase magnetism detection element Sα is not depicted in FIG. 3.

First, in order to satisfy β-phase layout conditional expression (5-2), the β-phase magnetism detection element SB needs to be disposed on the α-phase disposition line Lα within the disposition plane P, as with the α-phase magnetism detection element Sα. That is, the β-phase magnetism detection element SB needs to be disposed at a position where the distances thereof to the V-phase current line 6v and the W-phase current line 6w within the disposition plane P are equal (i.e., needs to be disposed on the α-phase disposition line Lα).

In order to satisfy β-phase layout conditional expression (5-2), the detection axis Oβ of the β-phase magnetism detection element Sβ needs to be orthogonal to a magnetic flux formed by a current flowing through the U-phase current line 6u. Thus, in a case where the three phase current lines 6u, 6v, and 6w are disposed next to each other at equal intervals as depicted in FIG. 3, the detection axis Oβ of the β-phase magnetism detection element Sβ needs to be parallel to the α-phase disposition line Lα within the disposition plane P, as exemplified in FIG. 3, in order to satisfy β-phase layout conditional expression (5-2). Accordingly, the β-phase magnetism detection element Sβ can satisfy β-phase layout conditional expression (5-2) by being disposed on the α-phase disposition line Lα such that the detection axis Oβ thereof is parallel to the α-phase disposition line Lα.

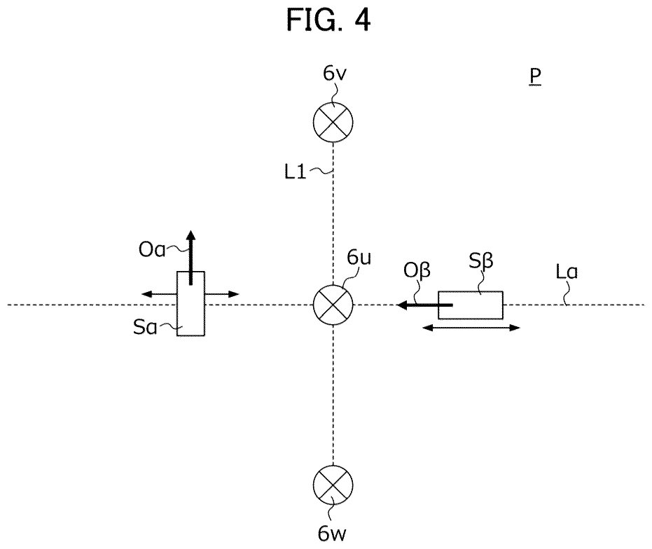

FIG. 4 illustrates a first example of the disposition layout of three phase current lines 6u, 6v, and 6w and two magnetism detection elements Sα and Sβ, the first example being for satisfying both α-phase layout conditional expression (5-1) and β-phase layout conditional expression (5-2) within a disposition plane P. Note that, as described above by referring to FIGS. 2 and 3, FIG. 4 depicts a situation in which the three phase current lines 6u, 6v, and 6w are disposed next to each other at equal intervals.

In a case where the three phase current lines 6u, 6v, and 6w are disposed next to each other at equal intervals in such a manner, the α-phase magnetism detection element Sα can satisfy α-phase layout conditional expression (5-1) when the detection axis Oα is disposed on the α-phase disposition line Lα in such a manner as to be orthogonal to the α-phase disposition line Lα. Meanwhile, the β-phase magnetism detection element Sβ can satisfy β-phase layout conditional expression (5-2) by being disposed on the α-phase disposition line Lα such that the detection axis Oβ is parallel to the β-phase disposition line LB.

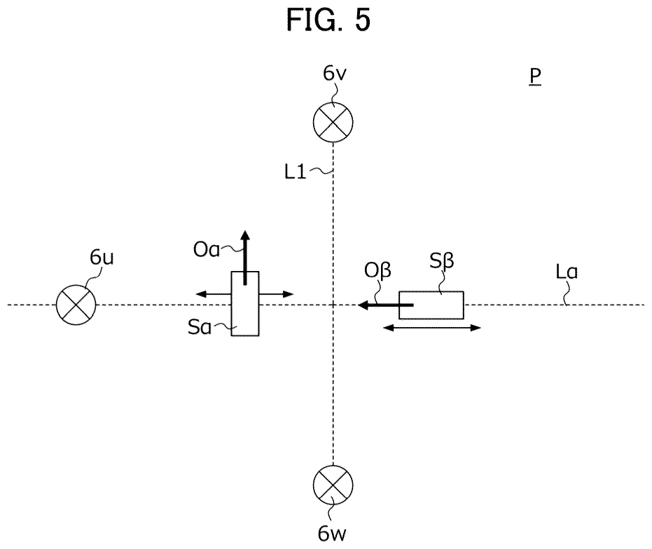

FIG. 5 illustrates a second example of the disposition layout of three phase current lines 6u, 6v, and 6w and two magnetism detection elements Sα and Sβ, the second example being for satisfying both α-phase layout conditional expression (5-1) and β-phase layout conditional expression (5-2) within a disposition plane P. FIG. 5 depicts a situation in which the phase current lines 6u, 6v, and 6w are disposed at the corners of an isosceles triangle having the U-phase current line 6u as the corner at a vertex angle.

In a case where the three phase current lines 6u, 6v, and 6w are disposed within the disposition plane P at the corners of an isosceles triangle as depicted in FIG. 5, the α-phase magnetism detection element Sα can also satisfy α-phase layout conditional expression (5-1) when the detection axis Oα is disposed on the α-phase disposition line Lα in such a manner as to be orthogonal to the α-phase disposition line Lα. Meanwhile, the β-phase magnetism detection element Sβ can satisfy β-phase layout conditional expression (5-2) by being disposed on the α-phase disposition line Lα such that the detection axis Oβ is parallel to the β-phase disposition line LB.

The current detection device 3 according to the present embodiment exhibits the following effects.
(1) The current detection device 3 detects currents flowing through the three phase current lines 6u, 6v, and 6w on the basis of the two magnetism detection elements Sα and Sβ provided in the vicinities of the phase current lines 6u, 6v, and 6w. Thus, the current detection device 3 allows for decreasing the number of magnetism detection elements in comparison with the conventional current detection device provided with one magnetism detection element for each single current line, so that the cost can be reduced accordingly. In the current detection device 3, the relative positions of the α-phase and β-phase magnetism detection elements Sα and Sβ and the orientations of the detection axes thereof with respect to the three phase current lines 6u, 6v, and 6w are set such that α-phase layout conditional expression (5-1) and β-phase layout conditional expression (5-2), which are defined using a factor X other than “−½,” are satisfied. Thus, according to the current detection device 3, expressions (5-1) and (5-2) include an arbitrary factor X, so the degree of freedom in the disposition layout of the three phase current lines 6u, 6v, and 6w and the two magnetism detection elements Sα and Sβ can be made higher than in the space Clarke transform described in the abovementioned earlier application by the applicant of the present application.

As described above, a current that is obtained by multiplying a three-phase current (Iu, Iv, Iw) having phases differing from each other by 2π/3 by the conversion matrix (X, −½, −½) indicated in α-phase layout conditional expression (5-1) is different only in amplitude from, but has the same phase as, a current that is obtained by multiplying the three-phase current (Iu, Iv, Iw) by the first-row elements (1, −½, −½) of the conversion matrix of the Clarke transform. This fact means that the output value Vα of the α-phase magnetism detection element Sα provided in such a manner as to satisfy α-phase layout conditional expression (5-1) can be made equal to the output value of the first magnetism detection element described in the earlier application by being multiplied by a prescribed gain. Thus, in the current detection device 3, the current correction calculation unit 22 outputs, as α-phase and β-phase current values (Iα, Iβ), the output values (Vα, Vβ) of the respective α-phase and β-phase magnetism detection elements Sα and Sβ with α-phase and β-phase gains (Gα, Gβ) multiplied thereby. The values of the α-phase and β-phase gains (Gα, Gβ) are set such that the amplitudes of the α-phase and β-phase current values (Iα, Iβ) are equal. Thus, in the current detection device 3, the calculation performed by the current correction calculation unit 22 allows for the cancellation of the difference in amplitude between the output values (Vα, Vβ) of the two magnetism detection elements Sα and SB that is caused by the factor X included in α-phase layout conditional expression (5-1). Thus, since the current detection device 3 uses the α-phase and β-phase current values (Iα, Iβ) output from the current correction calculation unit 22, the dq conversion unit 23, which is provided on a subsequent stage, does not need to perform the Clarke transform through calculation. Hence, the computational load on the motor control device 2 can be reduced accordingly, and the current detection device 3 can ultimately contribute to the improvement of energy efficiency.
(2) In the current detection device 3, the α-phase and β-phase magnetism detection elements Sα and Sβ can be provided within a disposition plane P orthogonal to the three phase current lines 6u, 6v, and 6w, thereby allowing the two magnetism detection elements Sα and Sβ to be gathered compactly and disposed in the vicinities of the three phase current lines 6u, 6v, and 6w, while satisfying α-phase layout conditional expression (5-1) and β-phase layout conditional expression (5-2).
(3) In the current detection device 3, the α-phase magnetism detection element Sα can be disposed on an imaginary α-phase disposition line Lα that is orthogonal to the line segment Li connecting the V-phase and W-phase current lines 6v and 6w within the disposition plane P and that bisects the line segment Li, thereby allowing the α-phase magnetism detection element Sα to be disposed at an arbitrary position meeting needs, while satisfying α-phase layout conditional expression (5-1) and β-phase layout conditional expression (5-2).
(4) In the current detection device 3, the three phase current lines 6u, 6v, and 6w can be disposed next to each other within the α-phase disposition plane Pa, thereby allowing the three phase current lines 6u, 6v, and 6w to be gathered compactly, while satisfying α-phase layout conditional expression (5-1) and β-phase layout conditional expression (5-2). Although the space Clarke transform described in the earlier application also allows the three phase current lines 6u, 6v, and 6w to be disposed next to each other, the U-phase current line 6u needs to be twisted because the orientation of the U-phase current line 6u, which is disposed in the middle, needs to be opposite to the orientation of the other two (see FIGS. 4 and 5 of the earlier application). In the current detection device 3, by contrast, the three phase current lines 6u, 6v, and 6w can be disposed next to each other without twisting the three phase current lines 6u, 6v, and 6w.
(5) In the current detection device 3, the three phase current lines 6u, 6v, and 6w can be disposed next to each other, and the α-phase and β-phase magnetism detection elements Sα and Sβ can be provided on the α-phase disposition line Lα passing the U-phase current line 6u, which is positioned in the middle, thereby allowing the three phase current lines 6u, 6v, and 6w and the two magnetism detection elements Sα and Sβ to be gathered compactly, while satisfying α-phase layout conditional expression (5-1) and β-phase layout conditional expression (5-2).
(6) In the current detection device 3, the β-phase magnetism detection element Sβ can be disposed on the α-phase disposition line Lα such that the detection axis Oβ thereof is parallel to the α-phase disposition line Lα, thereby allowing the β-phase magnetism detection element Sβ to be disposed near the U-phase current line 6u, while preventing the influence of a current flowing through the U-phase current line 6u from being exerted on the β-phase magnetism detection element SB.

One embodiment of the present invention has been described so far, but the present invention is not limited to this. The features of details may be changed, as appropriate, within the scope of the spirit of the present invention.

What is claimed is:

1. A current detection device for detecting currents flowing through a first current line, a second-phase current line, and a third-phase current line of a three-phase motor, the current detection device comprising:
an α-phase magnetism detection element and a β-phase magnetism detection element that are provided in vicinities of the first-phase, second-phase, and third-phase current lines; and
a calculator that outputs, as an α-phase current value and a β-phase current value, output values of the α-phase and β-phase magnetism detection elements with an α-phase gain and a β-phase gain respectively multiplied thereby, wherein assuming that I1 is a current value of the current flowing through the first-phase current line, I2 is a current value of the current flowing through the second-phase current line, I3 is a current value of the current flowing through the third-phase current line, Vα is the output value of the α-phase magnetism detection element, and VB is the output value of the β-phase magnetism detection element, relative positions of the α-phase and β-phase magnetism detection elements and orientations of detection axes thereof with respect to the first-phase, second-phase, and third-phase current lines are set such that expressions (1-1) and (1-2) below, which are defined using a factor X other than “−½,” are satisfied, and values of the α-phase and β-phase gains are set such that amplitudes of the α-phase and β-phase current values are equal.
$$V α ∝ ( \begin{matrix}X & - 1 / 2 & - 1 / 2\end{matrix} ) ( \begin{matrix}I 1 \\ I 2 \\ I 3\end{matrix} ) \qquad ( 1 - 1 )$$
$$V β ∝ ( \begin{matrix}0 & \sqrt{3} / 2 & - \sqrt{3} / 2\end{matrix} ) ( \begin{matrix}I 1 \\ I 2 \\ I 3\end{matrix} ) \qquad ( 1 - 2 )$$

2. The current detection device according to claim 1, wherein
the α-phase and β-phase magnetism detection elements are provided within a same disposition plane orthogonal to the first-phase, second-phase, and third-phase current lines.

3. The current detection device according to claim 2, wherein
the α-phase magnetism detection element is disposed on an imaginary disposition line that is orthogonal to a line segment connecting the second-phase current line and the third-phase current line within the disposition plane and that bisects the line segment.

4. The current detection device according to claim 3, wherein
the first-phase current line is orthogonal to the disposition plane at a point of intersection of the line segment and the disposition line, and
orientations of direct currents flowing from a power supply through the first-phase, second-phase, and third-phase current lines toward the three-phase motor are same within the disposition plane.

5. The current detection device according to claim 4, wherein
the β-phase magnetism detection element is disposed on the disposition line within the disposition plane.

6. The current detection device according to claim 5, wherein
the β-phase magnetism detection element is disposed on the disposition line such that the detection axis thereof is parallel to the disposition line.
